(19) United States
(12) Patent Application Publication
(10) Pub. No.: US 2006/0273817 A1
(43) Pub. Date: Dec. 7, 2006

(54) Wireless transmission device with a built-in antenna and a connector

(75) Inventors: Wen-Pin Hsieh, Taipei County (TW); Wen-Sheng Kuo, Taipei County (TW); Yen-Liang Kuan, Taipei County (TW)

Correspondence Address: BACON & THOMAS, PLLC, 625 SLATERS LANE, FOURTH FLOOR, ALEXANDRIA, VA, 22314, US

(73) Assignee: BEHAVIOR TECH COMPUTER CORP., Taipei County (TW)

(21) Appl. No.: 11/445,327

(22) Filed: Jun. 2, 2006

(30) Foreign Application Priority Data
Jun. 2, 2005 (CN) 94209164
Aug. 30, 2005 (CN) 94214878

(51) Int. Cl. G01R 31/26

(52) U.S. Cl. 324/765

(57) ABSTRACT

The invention provides a wireless transmission device, including a first circuit board, a second circuit board and a third circuit board. The first circuit board at least disposes more than one electronic elements. The second circuit board has an antenna, and the antenna is electrically connected to the first circuit board. The second circuit board is arranged at a predetermined angle to the first circuit board to enhance the receiving ability. The third circuit board is connected to the first circuit board and disposes a USB connector electrically connected to the first circuit board so that the change in form of the device can be easily made.

### BACKGROUND OF THE INVENTION

1. Field of the Invention

The invention relates to a wireless transmission device, and particularly relates to a wireless transmission device with an inclined built-in antenna to enhance the receiving ability. Besides, the wireless transmission device can be directly connected with a USB connector so that the change in form of the device can be easily made.

2. Description of the Prior Art

Referring to FIG. 1, the USB connector 105 and the antenna 104 in the conventional wireless transmission device 10 are set up on a printed circuit board 101, and a plurality of electronic elements 102 of other types, such as controllers, wireless transceiving modules, etc., are also set up on the same printed circuit board 101. The antenna 104 of the wireless transmission device 10 is fabricated by directly etching the copper foil covered on the surface of the printed circuit board 101. The USB connector 105 is directly soldered on the printed circuit board 101. All the electronic elements 102 and the printed circuit board 101 are received inside the housing 109, except for part of the USB connector 105 to be exposed outside the housing 109. Because of adopting the monolithic structure of the printed circuit board 101, whereon the electronic elements 102 and the antenna 104 are fixed on the same horizontal plane, and because of the USB connector 105 is also fixed on the printed circuit board 101, the form of the conventional wireless transmission device 10 presents simply the bar structure or the flat structure, hardly showing variations in appearance.

The patent application US 20020094779 titled “Wireless Communication Apparatus with Built-in Terminal Hub,” wherein all the electronic elements and the antenna are on the same horizontal plane, belongs to the structure of the said wireless transmission device 10. Thus the receiving ability of the wireless transmission device in the said patent application US 20020094779 may be limited. Besides, the form in appearance of the wireless transmission device in the said patent application may also be limited.

The inventor of the invention, in view of the drawbacks of the conventional wireless transmission device, ponders and improvement to create a wireless transmission device with an inclined built-in antenna to enhance the receiving ability and with the form in appearance to be easily changed.

### SUMMARY OF THE INVENTION

The main objective of the invention is to provide a wireless transmission device with an inclined built-in antenna to enhance the receiving ability. The wireless transmission device disposes a USB connector on a separate circuit board to connect with computers or other electronic apparatuses with USB connectivity such that the form in appearance of the wireless transmission device can be easily changed.

To achieve the said objective, one aspect of the invention provides a wireless transmission device comprising a first circuit board and a second circuit board. The first circuit board at least sets up a connector and more than one electronic elements. The second circuit board is arranged at a predetermined angle to the first circuit board, and at least has one antenna formed on the second circuit board. The said antenna is electrically connected with the first circuit board.

Another aspect of the invention provides a wireless transmission device comprising a connector; an antenna; a first circuit board, which disposes more than one electronic elements and disposes said connector or said antenna; and a second circuit board, which is connected to the first circuit board and disposes said connector or said antenna, said connector or said antenna being electrically connected to said first circuit board, wherein when said first circuit board disposes the said connector, said second circuit board disposes the said antenna; and when said first circuit board disposes the said antenna, said second circuit board disposes the said connector.

Another aspect of the invention provides a wireless transmission device, comprising a first circuit board, a second circuit board and a third circuit board. The first circuit board at least sets up more than one electronic element. The second circuit board is arranged at a predetermined angle to the first circuit board. The second circuit board at least has one antenna formed on the second circuit board and the said antenna is electrically connected with the first circuit board. The third circuit board sets up at least a connector.

Further another aspect of the invention provides a wireless transmission device, comprising a first circuit board. The first circuit board has a first region and a second region arranged at an predetermined angle to each other. The first region at least sets up more than one electronic elements. The second region at least has one antenna.

To make the objective, features and effects of the invention be understood by those skilled in this art, the invention is elaborated as follows by referring to the following embodiments and the accompanying figures.

### BRIEF DESCRIPTION OF THE DRAWINGS

FIG. 1 shows a schematic isometric view of a conventional wireless transmission device with a direct coupling USB connector.

FIG. 2 shows a schematic top view of the first embodiment according to the invention.

FIG. 3 shows a schematic side view of the first embodiment according to the invention.

FIG. 4 shows a schematic isometric view of the second embodiment according to the invention.

FIG. 5 shows a schematic isometric view of the third embodiment according to the invention.

FIG. 6 shows a schematic isometric view of the fourth embodiment according to the invention.

FIG. 7 shows a schematic isometric view of the fifth embodiment according to the invention.

FIG. 8 shows a schematic isometric view of the sixth embodiment according to the invention.

FIG. 9 shows a schematic isometric view of the seventh embodiment according to the invention.

FIG. 10 shows a schematic isometric view of the eighth embodiment according to the invention.

### DETAILED DESCRIPTION OF THE PREFERRED EMBODIMENTS

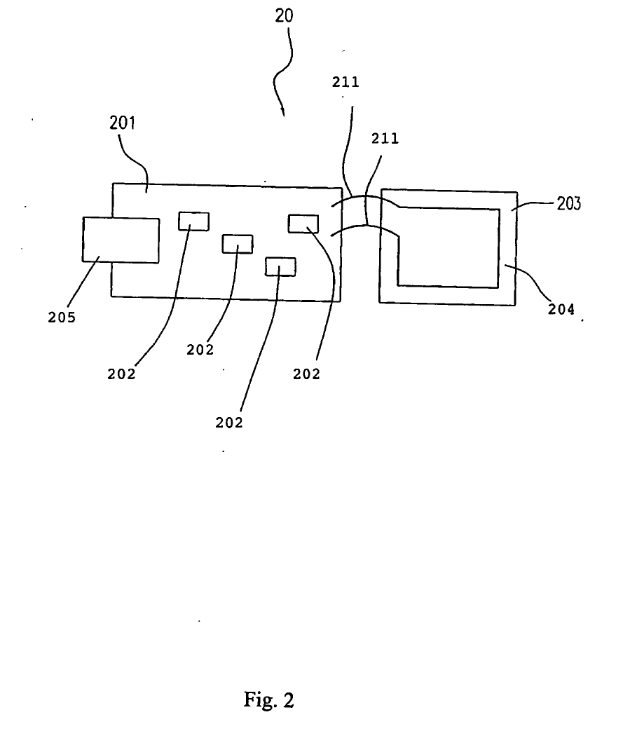

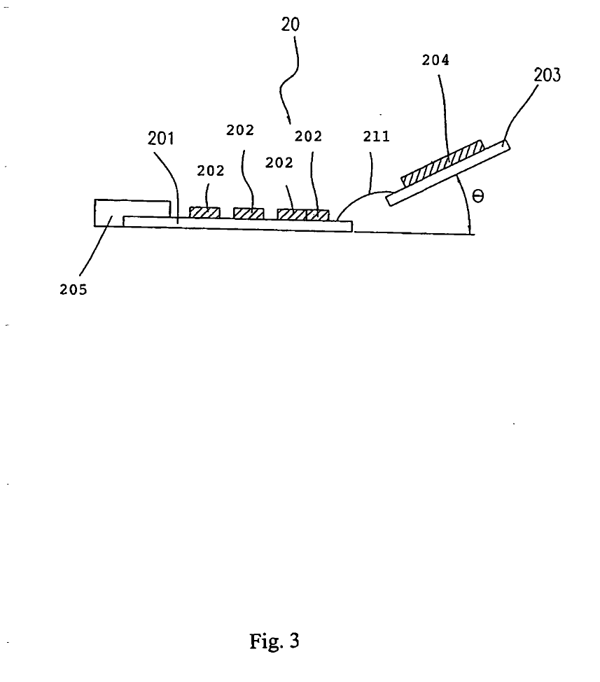

FIG. 2 shows a schematic top view of the first embodiment of the wireless transmission device according to the invention, and FIG. 3 shows a schematic side view of the first embodiment of the wireless transmission device according to the invention. The first embodiment according to the invention is a wireless transmission device 20 with an inclined built-in antenna, comprising a first circuit board 201, a second circuit board 203, more than one electronic elements 202, a connector 205, and an antenna 204. The second circuit board 203 is connected with the first circuit board 201, and the second circuit board 203 is connected at a predetermined angle to the first circuit board 201. The electronic elements 202 and the connector 205 are set up on the first circuit board 201, and the electronic elements 202 consist of, for example, resistors, capacitors, micro-controlling chips, wireless receiving modules, etc. The antenna 204 is set up on the second circuit board 203. Antenna 204 can be implemented by directly etching the copper foil on the second circuit board 203. The connector 205 may be, for example, a USB connector, and may also be, for example, a PS2 connector, an IR connector or connectors for other interfaces.

The means adopted to connect the second circuit board 203 and the first circuit board 201 may use the electric cables 211, such as copper-core conducting wires. The two ends of the copper-core conducting wire 211 are soldered on the second circuit board 203 and the first circuit board 201 respectively. The electronic elements 202 are electrically connected with the antenna 204 by the conductive property of the copper-core conducting wires 211. Meanwhile, the copper-core conducting wires 211 are bent so that the second circuit board 203 is connected at a predetermined angle to the first circuit board 201.

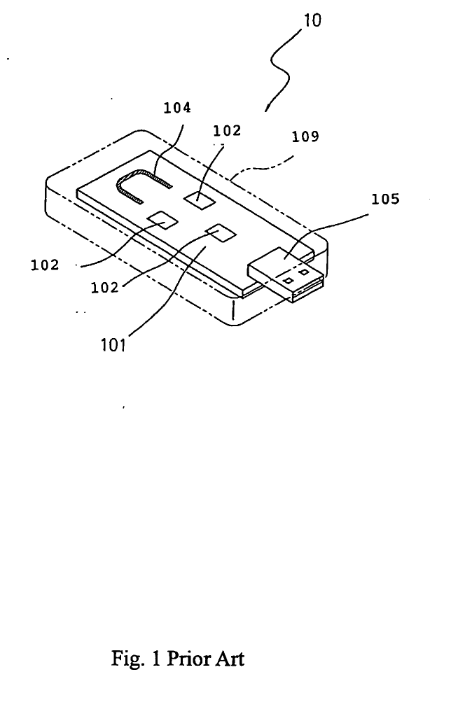

The plane of the second circuit board 203 whereon the antenna 204 is laid is different from the plane of the first circuit board 201, which leads to the plane of the antenna 204 at an angle θ to the first circuit board 201, referring to FIG. 3. Compared with, in FIG. 1, the plane of the antenna 104 and the plane of the printed circuit board 101 whereon the electronic elements 102 are set up, which is the traditional way wherein the two planes are arranged in the same level, the antenna 204 of the invention adopts the way of being inclinded at an angle θ so that the invention facilitates enhancing the receiving effect.

The structure of the wireless transmission device 20 with an inclined built-in antenna according to the invention may be implemented as a wireless receiver for a wireless mouse. The inclined built-in antenna 204 is arranged at an angle θ of 20 degrees and is placed on the wooden * table to conduct the tests on the receiving ability. The wireless mouse is operated to emit signals, and then the receiving ability of the wireless receiver 20 is within a range with a radius of 80 cm. By comparison, if the inclined built-in antenna 204 is otherwise arranged at an angle θ of 0 degree, the receiving ability of the wireless receiver 20 is within a range with a radius of 70 cm only. Besides, the inclined built-in antenna 204 is arranged at an angle θ of 20 degrees and is placed on the metallic table to conduct the tests on the receiving ability. The wireless mouse is operated to emit signals, and then the receiving ability of the wireless receiver 20 is within a range with a radius of 65 cm. By comparison, if the inclined built-in antenna 204 is otherwise arranged at an angle θ of 0 degree, the receiving ability of the wireless receiver 20 is within a range with a radius of 25 cm only. Although the metallic table will cause some interference in receiving the electric waves, the invention may, however, overcome the interference problems. Therefore, the antenna 204 according to the invention is so arranged to be at an angle greater than 0 degree that the invention facilitates enhancing the receiving effect.

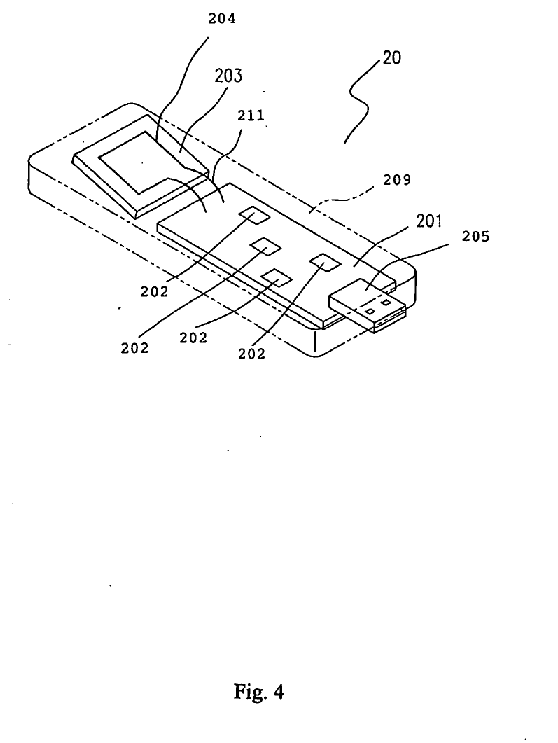

FIG. 4 shows a schematic isometric view of the second embodiment of the wireless transmission device according to the invention. The second embodiment of the wireless transmission device according to the invention is a wireless transmission device 20 with an inclined built-in antenna, which may further comprise a housing 209 to accommodate and receive the first circuit board 201 and the second circuit board 203. When a USB connector is adopted to be the connector 205, part of the USB connector 205 may be exposed outside the housing 209.

The electronic elements 202 and the connector 205 may be soldered on the first circuit board 201. The types of the electronic elements may vary with the implemented embodiments of the wireless transmission device 20. The implemented embodiment of the wireless transmission device 20 may be a wireless receiver for a wireless mouse, a wireless receiver for a wireless keyboard, a wireless receiver for a wireless keyboard-mouse set, a wireless transmitter, a wireless receiver or a wireless transceiver.

The said copper-core conducting wires 211 are adopted to be the connecting means between the second circuit board 203 and the first circuit board 201, which is to disclose the invention and make the invention easily understood. The invention is not confined to this type of connecting means, and any variation is within the scope of the equivalent means.

According to the invention, the antenna is set up on the second circuit board and the second circuit board is connected at an angle to the first circuit board in order to facilitate enhancing the receiving effect. This is one of the improved effects and advantages of the invention.

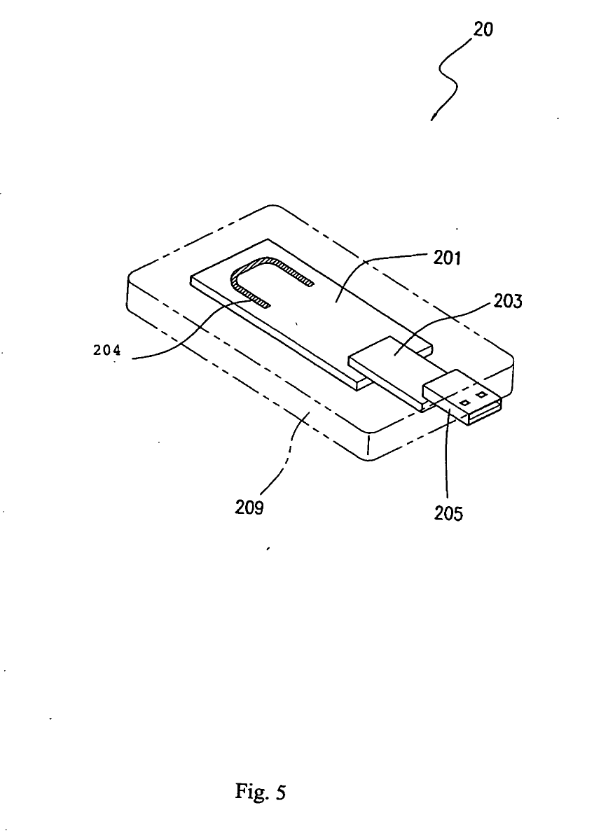

FIG. 5 shows a schematic isometric view of the third embodiment of the wireless transmission device according to the invention. The third embodiment of the wireless transmission device according to the invention is a wireless transmission device 20 which can be directly connected with a USB connector, comprising at least a first circuit board 201, a second circuit board 203, a connector 205, and an antenna 204. The second circuit board 203 is connected with the first circuit board 201. The connecting means adopted in the invention is, for example, the soldering means to directly solder the second circuit board 203 on the first circuit board 201. The connector 205 in the embodiment can be, for example, a USB connector, and the USB connector 205 is directly soldered on the second circuit board 203. The antenna 204 is directly formed on the first circuit board 201.

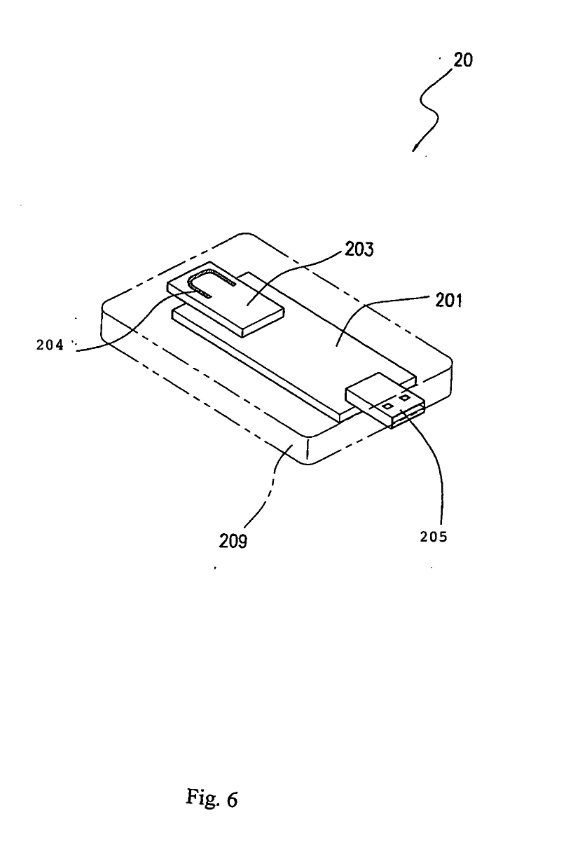

FIG. 6 shows a schematic isometric view of the fourth embodiment of the wireless transmission device according to the invention. The fourth embodiment of the wireless transmission device according to the invention is a wireless transmission device 20 which can be directly connected with a USB connector, comprising at least a first circuit board 201, a second circuit board 203, a connector 205, and an antenna 204. The second circuit board 203 is connected with the first circuit board 201. The connecting means adopted in the invention is, for example, the soldering means to directly solder the second circuit board 203 on the first circuit board 201. The antenna 204 is directly formed on the second circuit board 203, and the USB connector 205 is directly soldered on the first circuit board 201.

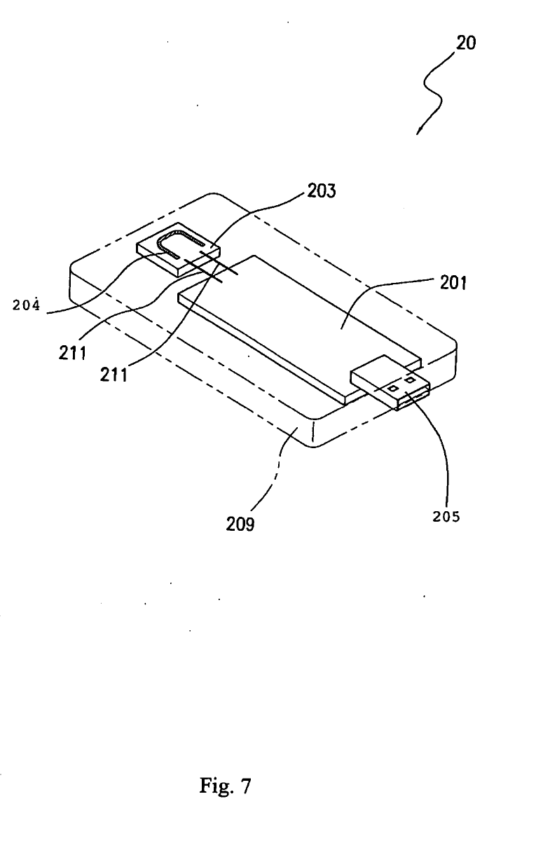

FIG. 7 shows a schematic isometric view of the fifth embodiment of the wireless transmission device according to the invention. The fifth embodiment of the wireless transmission device according to the invention is a wireless transmission device 20 which can be directly connected with a USB connector, comprising at least a first circuit board 201, a second circuit board 203, a connector 205, and an antenna 204. The second circuit board 203 is arranged separately from the first circuit board 201, and the second circuit board 203 is electrically connected with the first circuit board 201 by using the electric cables 211. The antenna 204 is directly formed on the second circuit board 203, and the USB connector 205 is directly soldered on the first circuit board 201.

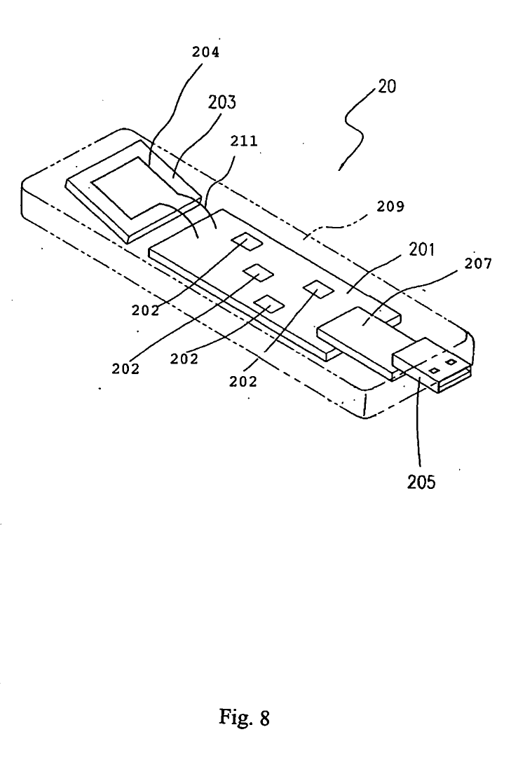

FIG. 8 shows a schematic isometric view of the sixth embodiment of the wireless transmission device according to the invention. The sixth embodiment of the wireless transmission device according to the invention is a wireless transmission device 20 with an inclined built-in antenna and with direct connectivity by a USB connector, comprising at least a first circuit board 201, a second circuit board 203, a third circuit board 207, a connector 205, and an antenna 204. The second circuit board 203 is connected with the first circuit board 201, and the second circuit board 203 is connected at a predetermined angle to the first circuit board 201. The third circuit board 207 is connected with the first circuit board 201. The connecting means adopted in the invention is, for example, the soldering means to directly solder the third circuit board 207 on the first circuit board 201. The connector 205 in the embodiment can be, for example, a USB connector, and the USB connector 205 is directly soldered on the third circuit board 207. The antenna 204 is directly formed on the first circuit board 201.

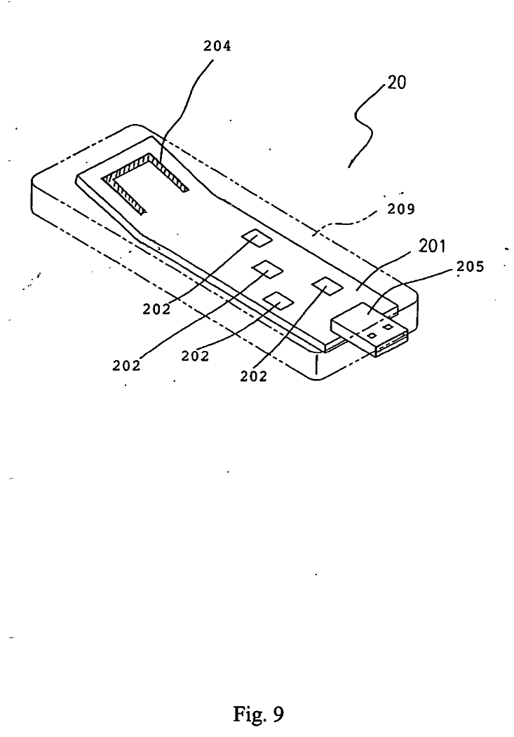

FIG. 9 shows a schematic isometric view of the seventh embodiment of the wireless transmission device according to the invention. The seventh embodiment of the wireless transmission device according to the invention is a wireless transmission device 20 with an inclined built-in antenna and with direct connectivity by a USB connector, comprising at least a first circuit board 201, a connector 205, and an antenna 204. The first circuit board 201 can be a flexible circuit board, wherein one part is a horizontal plane and the other part is an inclined plane at a predetermined angle to the part of the horizontal plane. The connector 205 in the embodiment can be, for example, a USB connector, and the USB connector 205 is set up on the first circuit board 201. The antenna 204 is directly formed on the part of the inclined plane of the first circuit board 201.

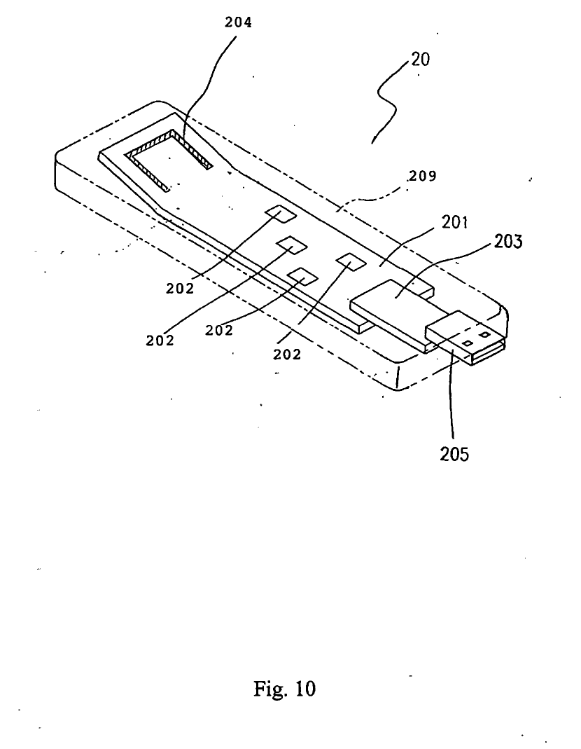

FIG. 10 shows the isometric view of the eighth embodiment of the wireless transmission device according to the invention. The eighth embodiment of the wireless transmission device according to the invention is a wireless transmission device 20 with an inclined built-in antenna and with direct connectivity by a USB connector, comprising at least a first circuit board 201, a second circuit board 203, a connector 205, and an antenna 204. The first circuit board 201 can be a flexible circuit board, wherein one part is a horizontal plane and the other part is an inclined plane at a predetermined angle to the part of the horizontal plane. The second circuit board 203 is connected with the part of the horizontal plane of the first circuit board 201. The connecting means adopted in the invention is, for example, the soldering means to directly solder the second circuit board 203 on the part of the horizontal plane of the first circuit board 201. The connector 205 in the embodiment can be, for example, a USB connector, and the USB connector 205 is directly soldered on the second circuit board 203. The antenna 204 is directly formed on the part of the inclined plane of the first circuit board 201.

In addition, in the third to the eighth embodiments of the invention, the wireless transmission device 20 which can be directly connected with a USB connector may further comprise a housing 209 to accommodate and receive the first circuit board 201, the second circuit board 203, the third circuit board and the connector 205. When the USB connector is adopted to be the connector 205, part of the USB connector 205 may be exposed outside the housing 209.

In addition, in the third to the eighth embodiments, the first circuit board 201 may be used to dispose some electronic elements 202. The electronic elements 202 consist of, for example, resistors, capacitors, micro-controlling chips, wireless receiving modules, etc. The types of the electronic elements soldered on the first circuit board 201 may vary with the implemented embodiments of the wireless transmission device 20. The implemented embodiment of the wireless transmission device 20 may be a wireless receiver for a wireless mouse, a wireless receiver for a wireless keyboard, a wireless receiver for a wireless keyboard-mouse set, a wireless transmitter, a wireless receiver or a wireless transceiver.

According to the invention, the parallel connecting means of the second circuit board 203 and the first circuit board 201 as shown in FIG. 5, 6 and 10 and the parallel connecting means of the third circuit board 207 and the first circuit board 201 as shown in FIG. 8 are to disclose the invention and make the invention easily understood. The invention is not confined to this parallel type of connecting means as shown in the figures. For example, the second circuit board 203 or the third circuit board 207 can be connected at a certain angle, formed either horizontally or vertically, to the first circuit board 201. The variations are within the scope of the equivalent means.

According to the invention, making the second circuit board 203 or the third circuit board 207, whereon the connector 205 is disposed, connected with the first circuit board 201, is completely different from the means used in the conventional wireless transmission device 10. With the variations of the form in appearance of the housing 209, the invention may easily dispose the connector 205, such as a USB connector, in an appropriate position of the housing 209 to satisfy the apparent integrity of the housing 209. This is one of the improved effects and advantages of the invention.

Although the invention is disclosed as above through the embodiments, the embodiments disclosed, however, are not to confine the invention. Anyone skilled in this art may, without deviating from the spirit and the scope of the invention, make various changes and modifications. The changes and modifications made are within the scope of the invention. The protective scope of the invention is determined by the following claims.

What is claimed is:

1. A wireless transmission device, comprising
a first circuit board, which at least disposes a connector and more than one electronic elements; and
a second circuit board, which is arranged at a predetermined angle to the first circuit board and which at least has an antenna formed on the second circuit board and electrically connected to the first circuit board.

2. The wireless transmission device according to claim 1, wherein the connector is a USB connector, a PS2 connector, or an IR connector.

3. The wireless transmission device according to claim 1, wherein the predetermined angle is greater than 0 degree and is between 0 and 90 degrees.

4. The wireless transmission device according to claim 1, wherein the antenna is fabricated by etching the copper foil of the second circuit board.

5. The wireless transmission device according to claim 1, wherein the electronic elements comprise a wireless receiving module and/or a micro-controlling chip.

6. The wireless transmission device according to claim 1, wherein the antenna of the second circuit board is electrically connected to the first circuit board by a cable with the two ends of the cable soldered on the first circuit board and the second circuit board, respectively.

7. The wireless transmission device according to claim 1, further comprising a housing to accommodate the first circuit board and the second circuit board, wherein part of the connector is exposed.

8. The wireless transmission device according to claim 1, wherein the connector is soldered on the first circuit board.

9. The wireless transmission device according to claim 1, wherein the wireless transmission device is a wireless receiver for a wireless mouse, a wireless receiver for a wireless keyboard, a wireless receiver for a wireless keyboard-mouse set, a wireless receiver, a wireless transmitter, or a wireless transceiver.

10. A wireless transmission device, comprising
a connector;
an antenna;
a first circuit board, which disposes more than one electronic elements and disposes said connector or said antenna; and
a second circuit board, which is connected to the first circuit board and disposes said connector or said antenna, said connector or said antenna being electrically connected to said first circuit board,
wherein when said first circuit board disposes said connector, said second circuit board disposes said antenna; and when said first circuit board disposes said antenna, said second circuit board disposes said connector.

11. The wireless transmission device according to claim 10, wherein the connector is a USB connector, a PS2 connector, or an IR connector.

12. The wireless transmission device according to claim 10, wherein the antenna is fabricated by etching the copper foil of the first circuit board or the second circuit board.

13. The wireless transmission device according to claim 10, wherein the electronic elements comprise a wireless receiving module and/or a micro-controlling chip.

14. The wireless transmission device according to claim 10, wherein the second circuit board is soldered on the first circuit board.

15. The wireless transmission device according to claim 10, wherein the connector or the antenna on the second circuit board is electrically connected to the first circuit board by a cable with the two ends of the cable soldered on the first circuit board and the second circuit board, respectively.

16. The wireless transmission device according to claim 10, further comprising a housing to accommodate the first circuit board, the second circuit board and the electronic elements, wherein part of the connector is exposed.

17. The wireless transmission device according to claim 10, wherein the connector is soldered on the second circuit board.

18. The wireless transmission device according to claim 10, wherein the wireless transmission device is a wireless receiver for a wireless mouse, a wireless receiver for a wireless keyboard, a wireless receiver for a wireless keyboard-mouse set, a wireless receiver, a wireless transmitter or a wireless transceiver.

19. A wireless transmission device, comprising
a first circuit board, which at least disposes more than one electronic elements;
a second circuit board, which is arranged at a predetermined angle to the first circuit board and which at least has one antenna formed on the second circuit board, said antenna being electrically connected to the first circuit board;
a third circuit board, which is connected to the first circuit board, and at least has one connector electrically connected to the first circuit board.

20. The wireless transmission device according to claim 19, wherein the connector is a USB connector, a PS2 connector, or an IR connector.

21. The wireless transmission device according to claim 19, wherein the predetermined angle is greater than 0 degree and is between 0 and 90 degrees.

22. The wireless transmission device according to claim 19, wherein the antenna is fabricated by etching the copper foil of the second circuit board.

23. The wireless transmission device according to claim 19, wherein the electronic elements comprise a wireless receiving module and/or a micro-controlling chip.

24. The wireless transmission device according to claim 19, wherein the antenna of the second circuit board is electrically connected to the first circuit board by a cable with the two ends of the cable soldered on the first circuit board and the second circuit board, respectively.

25. The wireless transmission device according to claim 19, wherein the third circuit board is directly soldered on the first circuit board.

26. The wireless transmission device according to claim 19, further comprising a housing to accommodate the first circuit board, the second circuit board, and the third circuit board, wherein part of the connector is exposed.

27. The wireless transmission device according to claim 19, wherein the connector is soldered on the third circuit board.

28. The wireless transmission device according to claim 19, wherein the wireless transmission device is a wireless receiver for a wireless mouse, a wireless receiver for a wireless keyboard, a wireless receiver for a wireless keyboard-mouse set, a wireless receiver, a wireless transmitter or a wireless transceiver.

29. A wireless transmission device, comprising
a first circuit board with a first region and a second region which are arranged at an predetermined angle to each other, the first region at least disposing more than one electronic elements, the second region at least disposing an antenna; and
a connector, which is electrically connected to the first circuit board.

30. The wireless transmission device according to claim 29, further comprising a second circuit board connected to the first circuit board and disposing said connector.

31. The wireless transmission device according to claim 29, wherein the first circuit board is a flexible circuit board.

32. The wireless transmission device according to claim 29, wherein the connector is a USB connector, a PS2 connector, or an IR connector.

33. The wireless transmission device according to claim 29, wherein the connector is connected to the first circuit board.

34. The wireless transmission device according to claim 29, wherein the predetermined angle is greater than 0 degree and is between 0 and 90 degrees.

35. The wireless transmission device according to claim 29, wherein the antenna is fabricated by etching the copper foil of the first circuit board.

36. The wireless transmission device according to claim 29, wherein the electronic elements comprise a wireless receiving module and/or a micro-controlling chip.

37. The wireless transmission device according to claim 30, wherein the second circuit board is soldered on the first circuit board.

38. The wireless transmission device according to claim 30, wherein the connector is soldered on the second circuit board.

39. The wireless transmission device according to claim 30, further comprising a housing to accommodate the first circuit board, the second circuit board, and the electronic elements, wherein part of the connector is exposed.

40. The wireless transmission device according to claim 29, wherein the wireless transmission device is a wireless receiver for a wireless mouse, a wireless receiver for a wireless keyboard, a wireless receiver for a wireless keyboard-mouse set, a wireless receiver, a wireless transmitter or a wireless transceiver.
